(19) United States
(12) Patent Application Publication
(10) Pub. No.: US 2014/0030655 A1
(43) Pub. Date: Jan. 30, 2014

(54) Enhanced Multi-Photon Imaging Resolution Method

(71) Applicant: Robert J. DeVoe, Mahtomedi, MN (US)

(72) Inventor: Robert J. DeVoe, Mahtomedi, MN (US)

(73) Assignee: 3M INNOVATIVE PROPERTIES COMPANY, St. Paul, MN (US)

(21) Appl. No.: 14/002,493

(22) PCT Filed: Apr. 17, 2012
(86) PCT No.: PCT/US12/33874

§ 371 Date: Aug. 30, 2013

Related U.S. Application Data
(60) Provisional application No. 61/478,180, filed on Apr. 22, 2011.

(51) Int. Cl. G03F 7/00; G03F 7/031

(52) U.S. Cl. CPC G03F 7/0037; G03F 7/031
USPC 430/287.1; 430/322

(57) ABSTRACT

A method and a multi-photon photocurable composition are provided that allow for the formation of a three-dimensional microstructure having enhanced imaging resolution. The method involves providing a multi-photon photocurable composition system having an acrylic prepolymer and a multiphotohn photoinitiator system that comprises at least one distyrylbenzene dye or a benzothiazolyl fluorine derivative. The method includes imagewise exposing at least one voxel of the photocurable composition to a dose of electromagnetic energy under conditions effective to photodefinably form at least one solid voxel of a three-dimensional microstructure having a volume, wherein the solid voxel volume varies inversely with the dose.

### FIELD

This disclosure broadly relates to methods for producing structures using multi-photon absorption polymerization, and more particularly, to methods for enhanced imaging resolution.

### BACKGROUND

Multi-photon curing processes may be useful for fabricating two-dimensional (2D) and/or three-dimensional (3D) structures with micro- or nano-scale resolution. For example, microfabrication of organic optical elements is described in U.S. Pat. No. 6,855,478 (DeVoe et al.). In these processes, a layer of material including a multi-photon curable photoreactive composition is applied on a substrate (e.g., a silicon wafer) and selectively cured using a focused source of radiant energy, such as an ultrafast laser beam.

In one such fabrication process, a voxel, three-dimensional (3D) volume element, is created when a pulsed laser beam of visible or near-infrared (NIR) radiation is focused into an engineered photopolymer resin. A non-linear interaction process within the resin initiates cure of the resin near a focus of the laser beam, where two photons of the NIR radiation are absorbed substantially simultaneously. The curing of the resin may be referred to as “photopolymerization” and the process may be referred to as a “two-photon photopolymerization” (2P) process. Photopolymerization of the resin does not occur in regions of the resin exposed to portions of the NIR radiation having an insufficient intensity, that is, an intensity lower than a threshold dose for initiating photopolymerization.

A 3D structure may be constructed voxel-by-voxel with a multi-photon photopolymerization process by controlling a location of the focus of the laser beam in three dimensions (i.e., x-axis, y-axis, and z-axis directions) relative to the resin. In many cases, 3D structures are formed by curing approximately single voxel layers (e.g., in the x-y plane), followed by moving the focal point about one voxel length (e.g., in the z-axis), and curing a subsequent layer (e.g., in the x-y plane). This process may be repeated until the desired structure is at least partially cured.

Typically, the focal point of the laser beam is approximately ellipsoidal, with an intensity profile that is roughly Gaussian along any diameter. Accordingly, the voxels cured by exposure to the laser beam are roughly ellipsoidal. The shape of the voxels at the focal point of the laser beam can limit the imaging resolution of 3D structures.

The demand for increasingly powerful compact electronics has necessitated the packing of transistors at ever higher densities into integrated circuits. This demand, in turn, has lead to the need for photolithography techniques that can have higher image resolution and that can allow for micro- or nanofabrication of ever smaller features. Recently, a method and system for photolithographic fabrication with resolution far below the diffraction limit has been disclosed in U.S. Pat. App. Publ. No. 2011/0039213 (Fourkas et al.). This method includes using a photoresist that includes a photoinitiator and a prepolymer resin. The method involves using a first light source focused on a first area of the photoresist to excite the photoinitiator and a second light source focused on a second area of the photoresist that can temporarily deactivate the photoinitiator excited by the first light source. The first area and the second area overlap at least partially.

More recently, M. P. Stocker et al., Nature Chemistry, 3, 223 (2011) has disclosed multi-photon photoresists that produce voxels that are proportion to the scan speed or voxels that are inversely dependent on exposure time, that is inversely dependent upon exposure time using single ultrafast 800 nm excitation laser pulses and three classes of common dye molecules that can act as photoinitiators with a line width having a proportional velocity dependence. These three classes of photoinitiators are cationic diarylmethanes, cationic triarylmethanes, and cationic (e.g, as typified by malachite green carbinol hydrochloride).

### SUMMARY

Thus, there is a need for other systems and methods which can allow for photolithographic fabrication of microstructures and nanostructures. There is also a need for systems and methods that can make high-fidelity microstructures and nanostructures that have increasingly small dimensions. Finally, there is a need for systems and methods that show enhanced multi-photon imaging resolution with increasing exposure.

In one aspect, a method of forming a three-dimensional microstructure is provided that includes providing a photocurable composition comprising a prepolymer comprising an acrylate monomer, and a multi-photon photoinitiator system comprising at least one substituted distyrylbenzene dye; and imagewise exposing at least one voxel of the photocurable composition to a dose of electromagnetic energy sufficient to cause simultaneous absorption of at least two photons, under conditions effective to photodefinably form at least one solid voxel of a three-dimensional microstructure having a volume, wherein the solid voxel volume varies inversely with to the dose. The prepolymer can include an alkoxylated multifunctional acrylate monomer as an adhesion promoter. The multi-photon photoinitiator system can further comprise an iodonium salt such as a diphenyliodonium salt and an electron donor compound such as an alkyl borate.

In another aspect, a multi-photon resin system is provided that includes providing a photocurable composition comprising a prepolymer comprising an acrylate monomer, and a multi-photon photoinitiator system comprising at least one chromophore having the formula, (T-Q)ₙ-N—Phₘ, wherein Q is a single bond or 1,4-phenylene, Ph is a phenyl group, n is 1-3, m has a value of (3-n) and (T-Q) has the formula:

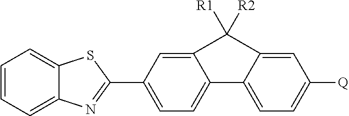

wherein R₄ and R₅ are alkyl groups having 1 to 20 carbon atoms provided that when Q is a single bond, the value of n is 2 or 3; and imagewise exposing at least one voxel of the photocurable composition to a dose of electromagnetic energy sufficient to cause simultaneous absorption of at least two photons, under conditions effective to photodefinably form at least one solid voxel of a three-dimensional microstructure having a volume, wherein the solid voxel volume varies inversely with the dose. The prepolymer can contain any of the additives described above.

In yet another aspect, a multi-photon resin system is provided that includes a photocurable composition comprising a prepolymer comprising an acrylate monomer, and a multi-photon photoinitiator system comprising at least one distyrylbenzene dye or one chromophore having the formula, (T-Q)ₙ-N-Phₘ, wherein Q is a single bond or 1,4-phenylene, Ph is a phenyl group, n is 1-3, m has a value of (3-n) and (T-Q) has the formula:

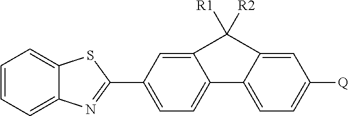

wherein R₁ and R₂ are alkyl groups having 1 to 20 carbon atoms provided that when Q is a single bond, the value of n is 2 or 3, wherein upon imagewise exposure of at least one voxel of the photocurable composition to a dose of electromagnetic energy under conditions effective to photodefinably form at least one solid voxel of a three-dimensional microstructure having a volume, and wherein the solid voxel volume varies inversely with the dose.

In the present disclosure:

“(meth)acryl” refers to materials derived from both “acryl” and “methacryl”;

“microstructure” refers to a 2D or 3D shape having at least one critical dimension less than about 800 microns (μm), typically less than about 500 microns or even less than 100 microns.

“nonlinear” refers to a process in which the absorption of actinic radiation is intensity or fluence dependent;

“photodefineable” or “photodefineably” refers to functionality directly or indirectly pendant from a monomer, oligomer, and/or polymer backbone (as the case may be) that participates in crosslinking reactions upon exposure to a suitable source of electromagnetic energy;

“simultaneous” means two events that occur within the period of 10⁻¹⁴ seconds or less;

“solid” refers to a composition that can resist flow enough to hold its form for a long period of time such as days, weeks, and even months;

“threshold value” refers to the amount of dose of electromagnetic radiation required to allow two-photon absorption to occur;

“two-photon absorption” refers to the process wherein a molecule absorbs two quanta of electromagnetic radiation to reach an excited state; and

“voxel” refers to a volume element within a three-dimensional space;

The provided methods and multi-photon resin systems can allow for photolithographic fabrication of microstructures and nanostructures with enhanced image resolution. They can be used to make high-fidelity structures that have increasingly small dimensions. These methods and resin systems can create solid voxels that have volumes that vary inversely with dose of electromagnetic energy.

The above summary is not intended to describe each disclosed embodiment of every implementation of the present invention. The brief description of the drawings and the detailed description which follows more particularly exemplify illustrative embodiments.

### BRIEF DESCRIPTION OF THE DRAWINGS

FIG. 1 schematically illustrates one methodology for producing three-dimensional articles.

FIG. 2 is an illustration of a two-dimensional 15-line structure used to determine threshold conditions and voxel height.

FIG. 3 is a graph of voxel height vs. 1/writing speed (sec/μm) at different power levels for a comparative example.

FIG. 4 is a graph of voxel height vs. 1/writing speed (sec/μm) for three exemplary and two comparative films.

FIG. 5 is a graph of voxel height vs. 1/writing speed (sec/μm) for three exemplary films.

### DETAILED DESCRIPTION

In the following description, reference is made to the accompanying set of drawings that form a part of the description hereof and in which are shown by way of illustration several specific embodiments. It is to be understood that other embodiments are contemplated and may be made without departing from the scope or spirit of the present invention. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g., 1 to 5 includes 1, 1.5, 2, 2.75, 3, 3.80, 4, and 5) and any range within that range.

A method of forming a three-dimensional microstructure or nanostructure is provided. The provided method includes a photocurable composition that includes a prepolymer comprising acrylate monomers and a multi-photon photoinitiator system that includes at least one distyrylbenzene dye. The prepolymer can be made from monomers, oligomers, or lower molecular weight polymers that can have reactive functionality and can polymerize and/or crosslink to form a solid. Examples of components of the polymerizable mixture include, for example, addition-polymerizable monomers and oligomers and addition-crosslinkable polymers (such as free-radically polymerizable or crosslinkable ethylenically-unsaturated species including, for example, acrylates, methacrylates, and certain vinyl compounds such as styrenes), and mixtures thereof. The provided prepolymer includes acrylate monomers as at least one of the ethylenically-unsaturated species.

Suitable ethylenically-unsaturated species are described, for example, by Palazzotto et al. in U.S. Pat. No. 5,545,676, and include mono-, di-, and poly-acrylates and methacrylates (for example, methyl acrylate, methyl methacrylate, ethyl acrylate, isopropyl methacrylate, n-hexyl acrylate, stearyl acrylate, allyl acrylate, glycerol diacrylate, glycerol triacrylate, ethylene glycol diacrylate, diethylene glycol diacrylate, triethylene glycol dimethacrylate, 1,3-propanediol diacrylate, 1,3-propanediol dimethacrylate, trimethylolpropane triacrylate, 1,2,4-butanetriol trimethacrylate, 1,4-cyclohexanediol diacrylate, pentaerythritol triacrylate, pentaerythritol tetraacrylate, pentaerythritol tetramethacrylate, sorbitol hexacrylate, bis[1-(2-acryloxy)]-p-ethoxyphenyldimethylmethane, bis[1-(3-acryloxy-2-hydroxy)]-p-propoxyphenyldimethylmethane, tris-hydroxyethyl-isocyanurate trimethacrylate, the bisacrylates and bismethacrylates of polyethylene glycols of molecular weight about 200-500, copolymerizable mixtures of acrylated monomers such as those of U.S. Pat. No. 4,652,274 (Boettcher et al.), and acrylated oligomers such as those of U.S. Pat. No. 4,642,126 (Zador et al.)); unsaturated amides (for example, methylene bisacrylamide, methylene bismethacrylamide, 1,6-hexamethylene bisacrylamide, diethylene triamine tris-acrylamide and beta-methacrylaminoethyl methacrylate); vinyl compounds (for example, styrene, diallyl phthalate, divinyl succinate, divinyl adipate, and divinyl phthalate); and mixtures thereof. Suitable reactive polymers include polymers with pendant (meth)acrylate groups, for example, having from 1 to about 50 (meth)acrylate groups per polymer chain. Examples of such polymers include aromatic acid (meth)acrylate half ester resins such as SARBOX resins available from Sartomer (for example, SARBOX 400, 401, 402, 404, and 405). Other useful reactive polymers curable by free radical chemistry include those polymers that have a hydrocarbyl backbone and pendant peptide groups with free-radically polymerizable functionality attached thereto, such as those described in U.S. Pat. No. 5,235,015 (Ali et al.). Mixtures of two or more monomers, oligomers, and/or reactive polymers can be used, if desired. In some embodiments, ethylenically-unsaturated species include acrylates, aromatic acid (meth)acrylate half ester resins, and polymers that have a hydrocarbyl backbone and pendant peptide groups with free-radically polymerizable functionality attached thereto.

In some embodiments, the prepolymer can include acrylic oligomers such as poly(methyl methacrylate) (PMMA) dissolved in a solvent along with acrylate monomers. For example, PMMA having a weight average molecular weight of 120,000 can be dissolved in cyclopentanone along with combinations of the multifunctional acrylate monomers listed above.

Other ingredients which may be incorporated in the composition include monohydroxy and polyhydroxy compounds, thixotropic agents, plasticizers, toughening agents, pigments, fillers, abrasive granules, stabilizers, light stabilizers, antioxidants, flow agents, bodying agents, flatting agents, colorants, binders, blowing agents, fungicides, bactericides, surfactants, glass and ceramic beads, and reinforcing materials such as woven and non-woven webs of organic and inorganic fibers.

The provided method of forming a three-dimensional microstructure includes a multi-photon photoinitiator system that includes at least one distyrylbenzene dye. Distyrylbenzene dyes are described, for example, in U.S. Pat. No. 6,267,913 (Marder et al.) as compounds capable of simultaneous two-photon absorption and higher order absorptions. Distyrylbenzene dyes of interest in this disclosure have the following general structure (I).

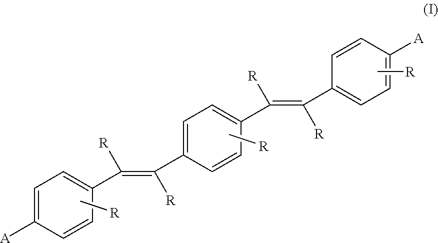

Each R can be, independently, an alkyl group, a branched alkyl group, an aromatic group, and a substituted aromatic group. In some embodiments, R groups can include alkyl groups such as methyl, ethyl, propyl, butyl, morpholino, phthalimido, and aromatic groups such as phenyl. The phenyl group may have additional substitution on the ring such as, for example, a methyl group, a methoxy group, a halogen such as fluorine, trifluoromethane, or a cyano group in one or more of the ring positions. In some embodiments, R can include H, chloro, bromo, fluoro, methoxy, ethoxy, propoxy, butoxy, or cyano. A is, independently, H, Cl, Br, NR₃R₄, OR₅, alkyl, alkenyl, aryl, and O(C═O)R₆, wherein R₃ to R₆ are, independently, methyl, ethyl, propyl, butyl, hydroxymethyl, hydroxyethyl, hydroxypropyl, hydroxybutyl, morphylino, phthalimido, or phenyl, and wherein the phenyl group, if present, is substituted on each ring position, independently, with H, methyl, ethyl, methoxy, ethyoxy, fluorine, trifluoromethane, or cyano. In some embodiments, the distyrylbenzene dyes can have the following structures ((II-IV)).

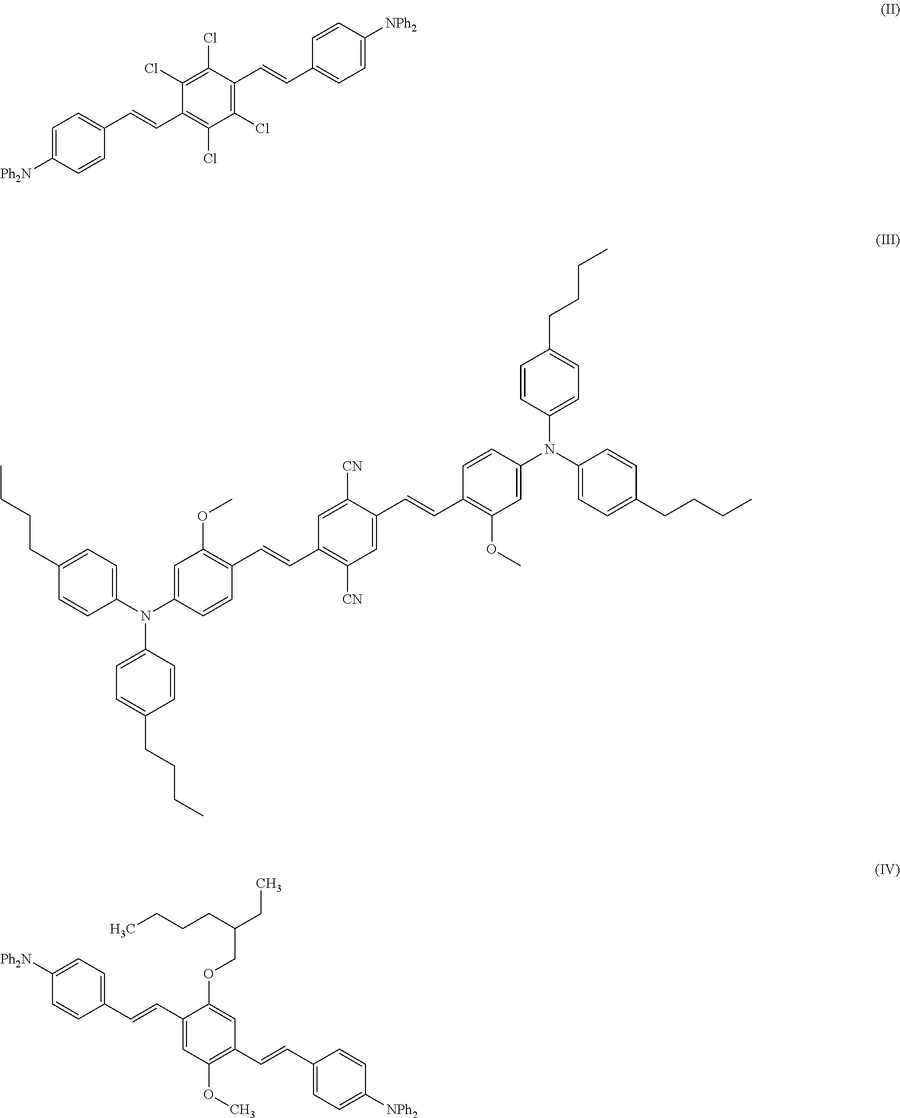

The distyrylbenzene dye can be used alone or in combination with other compounds in the multi-photon photoinitiator system. The multi-photon photoinitiator system of the present invention includes at least one distyrylbenzene dye multi-photon photosensitizer and, optionally, at least one photoinitiator that is capable of being photosensitized by the photosensitizer. An electron donor compound may also be included as an optional ingredient. While not wishing to be bound by theory, it is believed that light of sufficient intensity and appropriate wavelength to affect multi-photon absorption can cause the multi-photon photosensitizer to be in an electronic excited state via absorption of two photons, whereas such light is generally not capable of directly causing the photodefinable materials to be in an electronic excited state. The photosensitizer is believed to then transfer an electron to the photoinitiator, causing the photoinitiator to be reduced. The reduced photoinitiator can then cause the photodefinable materials to undergo the desired curing reactions. As used herein, “cure” means to effect polymerization and/or to effect crosslinking. Thus, by appropriate focusing of such light, photodefining can be controllably induced in the volume of focus with relatively high resolution to form optical elements with simple or complex, three-dimensional geometry, as desired.

Multi-photon photosensitizers are known in the art and illustrative examples having relatively large multi-photon absorption cross-sections have generally been described, for example, in U.S. Pat. No. 6,267,913 (Marder et al.). Although multi-photon cross-sections greater than fluorescein are not necessary for carrying out the present invention, typically, multi-photon photosensitizers suitable for use in the multi-photon photoinitiator system of the provided photocurable compositions are those that are capable of simultaneously adsorbing at least two photons when exposed to sufficient light and that have a two-photon adsorption cross-section greater than that of fluorescein (that is, greater than that of 3′,6′-dihydroxyspiro[isobenzofuran-1(3H), 9′-[9H]xanthen]3-one). Generally, the cross-section can be greater than about 50×10⁻⁵° cm⁴ sec/photon, as measured by the method described by C. Xu and W. W. Webb in J. Opt. Soc. Am. B, 13, 481 (1996) (which is referenced in PCT Publ. No. WO 98/21521 (Marder et al.)

This method (Xu and Webb) involves the comparison (under identical excitation intensity and photosensitizer concentration conditions) of the two-photon fluorescence intensity of the photosensitizer with that of a reference compound. The reference compound can be selected to match as closely as possible the spectral range covered by the photosensitizer absorption and fluorescence. In one possible experimental set-up, an excitation beam can be split into two arms, with 50% of the excitation intensity going to the photosensitizer and 50% to the reference compound. The relative fluorescence intensity of the photosensitizer with respect to the reference compound can then be measured using two photomultiplier tubes or other calibrated detector. Finally, the fluorescence quantum efficiency of both compounds can be measured under one-photon excitation.

Assuming that the emitting state is the same under one- and two-photon excitation (a common assumption), the two-photon absorption cross-section of the photosensitizer, (δₛₐₘ), is equal to δ_{ref}(Iₛₐₘ/I_{ref})(φₛₐₘ/φ_{ref}), wherein δ_{ref} is the two-photon absorption cross-section of the reference compound, Iₛₐₘ is the fluorescence intensity of the photosensitizer, I_{ref} is the fluorescence intensity of the reference compound, φₛₐₘ is the fluorescence quantum efficiency of the photosensitizer, and φ_{ref} is the fluorescence quantum efficiency of the reference compound. To ensure a valid measurement, the clear quadratic dependence of the two-photon fluorescence intensity on excitation power can be confirmed, and relatively low concentrations of both the photosensitizer and the reference compound can be utilized (to avoid fluorescence reabsorption and photosensitizer aggregation effects).

Although not necessary for carrying out the present invention, typically the two-photon absorption cross-section of the photosensitizer is greater than about 1.5 times that of fluorescein (or, alternatively, greater than about 75×10⁻⁵⁰ cm⁴ sec/photon, as measured by the above method); more preferably, greater than about twice that of fluorescein (or, alternatively, greater than about 100×10⁻⁵⁰ cm⁴ sec/photon); most preferably, greater than about three times that of fluorescein (or, alternatively, greater than about 150×10⁻⁵⁰ cm⁴ sec/photon); and optimally, greater than about four times that of fluorescein (or, alternatively, greater than about 200×10⁻⁵° cm⁴ sec/photon).

A multi-photon photosensitizer can also be selected based in part upon shelf stability considerations. Accordingly, selection of a particular photosensitizer can depend to some extent upon the particular reactive species utilized (as well as upon the choices of electron donor compound and/or photoinitiator, if either of these are used).

Typically, multi-photon photosensitizers for the provided method and resin system include those exhibiting large multi-photon absorption cross-sections, such as distyrylbenzene dyes as described above and the four classes of photosensitizers described, for example, in U.S. Pat. No. 6,297,913 (Marder et al.). The four classes can be described as follows: (a) molecules in which two donors are connected to a conjugated π (pi)-electron bridge; (b) molecules in which two donors are connected to a conjugated π (pi)-electron bridge which is substituted with one or more electron accepting groups; (c) molecules in which two acceptors are connected to a conjugated π (pi)-electron bridge; and (d) molecules in which two acceptors are connected to a conjugated π (pi)-electron bridge which is substituted with one or more electron donating groups (where “bridge” means a molecular fragment that connects two or more chemical groups, “donor” means an atom or group of atoms with a low ionization potential that can be bonded to a conjugated π (pi)-electron bridge, and “acceptor” means an atom or group of atoms with a high electron affinity that can be bonded to a conjugated π (pi)-electron bridge). The four above-described classes of photosensitizers can be prepared by reacting aldehydes with ylides under standard Wittig conditions or by using the McMurray reaction, as detailed in PCT Pat. Publ. No. WO 98/21521 (Marder et al.).

Other multi-photon photosensitizer compounds are for example, in U.S. Pat. Nos. 6,100,405; 5,859,251; 5,770,737; and U.S. Pat. Appl. Publ. No. 2008/0139683 (all to Reinhardt et al.) as having large multi-photon absorption cross-sections, although these cross-sections were determined by a method other than that described herein. In some embodiments, the photosensitizer includes at least one chromophore having the formula:

(T-Q)ₙ-N-Phₘ

Q can be a single bond or 1,4-phenylene, n can be 1 to 3, and m has a value of (3-n). (T-Q) has the formula

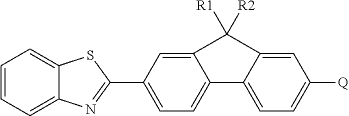

R₁ and R₂ can be alkyl groups having from 1 to 20 carbon atoms provided that when Q is a single bond, the value of n is 2 or 3. In one embodiment, the provided photosensitizer can have the following structure (Structure (V)).

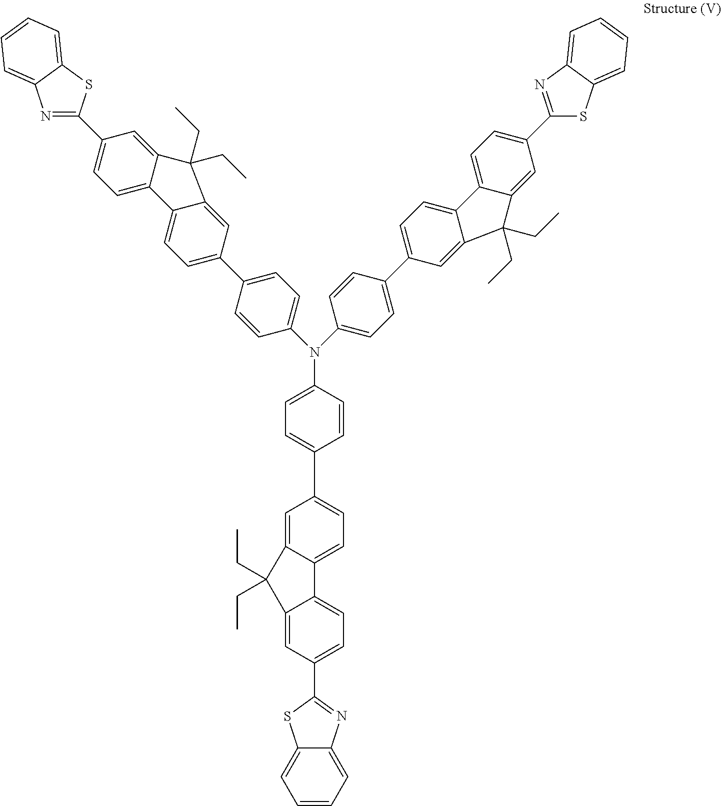 [SMILES: CCC1(CC)c2cc(-c3ccc(N(c4ccc(-c5ccc6c(c5)C(CC)(CC)c5cc(-c7nc8ccccc8s7)ccc5-6)cc4)c4ccc(-c5ccc6c(c5)C(CC)(CC)c5cc(-c7nc8ccccc8s7)ccc5-6)cc4)cc3)ccc2-c2ccc(-c3nc4ccccc4s3)cc21]

The multi-photon initiator system generally includes an amount of the multi-photon photosensitizer that is effective to facilitate photopolymerization within the focal region of the energy being used for imagewise curing. Using from about 0.01 to about 10, preferably 0.1 to 5, parts by weight of the multi-photon initiator per 5 to 100 parts by weight of the photodefinable material(s) would be suitable in the practice of the present invention.

The multi-photon photoinitiator system can also include a cationic initiator such as, for example, an onium salt (for example, an iodonium or sulfonium salt). Suitable iodonium salts include those described in U.S. Pat. No. 5,545,676 (Palazzotto et al.). Suitable iodonium salts are also described in U.S. Pat. Nos. 3,729,313, 3,741,769, 3,808,006, 4,250,053 and 4,394,403 (all to Smith). The iodonium salt can be a simple salt (for example, containing an anion such as Cl⁻, Br⁻, I⁻ or C₄H₅ SO₃⁻) or a metal complex salt (for example, containing SbF₆⁻, PF₆⁻, BF₄⁻, tetrakis(perfluorophenyl)borate, SbF₅ OH⁻ or AsF₆⁻). Mixtures of iodonium salts can be used if desired.

Examples of useful aromatic iodonium complex salt photoinitiators include diphenyliodonium tetrafluoroborate; di(4-methylphenyl)iodonium tetrafluoroborate; phenyl-4-methylphenyliodonium tetrafluoroborate; di(4-heptylphenyl)iodonium tetrafluoroborate; di(3-nitrophenyl)iodonium hexafluorophosphate; di(4-chlorophenyl)iodonium hexafluorophosphate; di(naphthyl)iodonium tetrafluoroborate; di(4-trifluoromethylphenyl)iodonium tetrafluoroborate; diphenyliodonium hexafluorophosphate; di(4-methylphenyl)iodonium hexafluorophosphate; diphenyliodonium hexafluoroarsenate; di(4-phenoxyphenyl)iodonium tetrafluoroborate; phenyl-2-thienyliodonium hexafluorophosphate; 3,5-dimethylpyrazolyl-4-phenyliodonium hexafluorophosphate; diphenyliodonium hexafluoroantimonate; 2,2′-diphenyliodonium tetrafluoroborate; di(2,4-dichlorophenyl)iodonium hexafluorophosphate; di(4-bromophenyl)iodonium hexafluorophosphate; di(4-methoxyphenyl)iodonium hexafluorophosphate; di(3-carboxyphenyl)iodonium hexafluorophosphate; di(3-methoxycarbonylphenyl)iodonium hexafluorophosphate; di(3-methoxysulfonylphenyl)iodonium hexafluorophosphate; di(4-acetamidophenyl)iodonium hexafluorophosphate; di(2-benzothienyl)iodonium hexafluorophosphate; and diphenyliodonium hexafluoroantimonate; and the like; and mixtures thereof. Aromatic iodonium complex salts can be prepared by metathesis of corresponding aromatic iodonium simple salts (such as, for example, diphenyliodonium bisulfate) in accordance with the teachings of Beringer et al., J. Am. Chem. Soc., 81, 342 (1959).

Typical iodonium salts include diphenyliodonium salts (such as diphenyliodonium chloride, diphenyliodonium hexafluorophosphate, and diphenyliodonium tetrafluoroborate), diaryliodonium hexafluoroantimonate (for example, SARCAT CD 1012 obtained from Sartomer Company), and mixtures thereof.

Useful chloromethylated triazines include those described in U.S. Pat. No. 3,779,778 (Smith et al.) at column 8, lines 45-50, which include 2,4-bis(trichloromethyl)-6-methyl-s-triazine, 2,4,6-tris(trichloromethyl)-s-triazine, and the more preferred chromophore-substituted vinylhalomethyl-s-triazines disclosed in U.S. Pat. Nos. 3,987,037 and 3,954,475 (both to Bonham et al.).

Useful sulfonium salts include those described in U.S. Pat. No. 4,250,053 (Smith) which can be represented by the formulas:

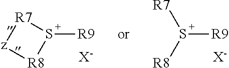

wherein R₇, R₈, and R₉ are each independently selected from aromatic groups having from about 4 to about 20 carbon atoms (for example, substituted or unsubstituted phenyl, naphthyl, thienyl, and furanyl, where substitution can be with such groups as alkoxy, alkylthio, arylthio, halogen, arylsulfonium, and so forth) and alkyl groups having from 1 to about 20 carbon atoms. As used here, the term “alkyl” includes substituted alkyl (for example, substituted with such groups as halogen, hydroxy, alkoxy, or aryl). At least one of R₇, R₈, and R₉ is aromatic, and, preferably, each is independently aromatic. Z is selected from the group consisting of a covalent bond, oxygen, sulfur, —S(═O)—, —C(═O)—, —(O═)S(═O)—, and —N(R₁₀)—, where R₁₀ is aryl (of about 6 to about 20 carbons, such as phenyl), acyl (of about 2 to about 20 carbons, such as acetyl, benzoyl, and so forth), a carbon-to-carbon bond, or —(R₁₁—)C(—R₁₂)—, where R₁₁ and R₁₂ are independently selected from the group consisting of hydrogen, alkyl groups having from 1 to about 4 carbon atoms, and alkenyl groups having from about 2 to about 4 carbon atoms. X⁻ is an anion, as described below.

Suitable anions, X⁻, for the sulfonium salts (and for any of the other types of photoinitiators) include a variety of anion types such as, for example, imide, methide, boron-centered, phosphorous-centered, antimony-centered, arsenic-centered, and aluminum-centered anions.

Illustrative, but not limiting, examples of suitable imide and methide anions include (C₂F₅SO₂)₂N⁻, (C₄F₉SO₂)₂N⁻, (C₈F₁₇SO₂)₃C⁻, (CF₃SO₂)₃C⁻, (CF₃SO₂)₂N⁻, (C₄F₉SO₂)₃C⁻, (CF₃SO₂)₂(C₄F₉SO₂)C⁻, (CF₃SO₂)(C₄F₉SO₂)N⁻, ((CF₃)₂NC₂F₄SO₂)₂N⁻, (CF₃)₂NC₂F₄SO₂C⁻(SO₂CF₃)₂, (3,5-bis(CF₃)C₆H₃)SO₂N—SO₂CF₃, C₆H₅SO₂C⁻(SO₂CF₃)₂, C₆H₅SO₂N⁻SO₂CF₃, and the like. Preferred anions of this type include those represented by the formula (R_{f}SO₂)₃C⁻, wherein R_{f} is a perfluoroalkyl radical having from 1 to about 4 carbon atoms.

Illustrative, but not limiting, examples of suitable boron-centered anions include F₄B⁻, (3,5-bis(CF₃)C₆H₃)₄B⁻, (C₆F₅)₄B⁻, (p-CF₃C₆H₄)₄B⁻, (m-CF₃C₆H₄)₄B⁻, (p-FC₆H₄)₄B⁻, (C₆F₅)₃(CH₃)B⁻, (C₆F₅)₃(n-C₄H₉)B⁻, (p-CH₃C₆H₄)₃(C₆F₅)B—, (C₆F₅)₃FB⁻, (C₆H₅)₃(C₆F₅)B⁻, (CH₃)₂(p-CF₃C₆H₄)₂B⁻, (C₆F₅)₃(n-C₁₈H₃₇O)B⁻, and the like. Preferred boron-centered anions generally contain 3 or more halogen-substituted aromatic hydrocarbon radicals attached to boron, with fluorine being the most preferred halogen. Illustrative, but not limiting, examples of the preferred anions include (3,5-bis(CF₃)C₆H₃)₄B⁻, (C₆F₅)₄B⁻, (C₆F₅)₃(n-C₄H₉)B⁻, (C₆F₅)₃FB⁻, and (C₆F₅)₃(CH₃)B⁻.

Suitable anions containing other metal or metalloid centers include, for example, (3,5-bis(CF₃)C₆H₃)₄Al⁻, (C₆F₅)₄Al⁻, (C₆F₅)₂F₄P⁻, (C₆F₅)F₅P⁻, F₆P⁻, (C₆F₅)F₅Sb⁻, F₆Sb⁻, (HO)F₅Sb⁻, and F₆As⁻. The foregoing lists are not intended to be exhaustive, as other useful boron-centered normucleophilic salts, as well as other useful anions containing other metals or metalloids, will be readily apparent (from the foregoing general formulas) to those skilled in the art.

Typically, the anion, X⁻, is selected from tetrafluoroborate, hexafluorophosphate, hexafluoroarsenate, hexafluoroantimonate, and hydroxypentafluoroantimonate.

Examples of suitable sulfonium salt photoinitiators include:
triphenylsulfonium tetrafluoroborate, methyldiphenylsulfonium tetrafluoroborate, dimethylphenylsulfonium hexafluorophosphate, triphenylsulfonium hexafluorophosphate, triphenylsulfonium hexafluoroantimonate, diphenylnaphthylsulfonium hexafluoroarsenate, tritolysulfonium hexafluorophosphate, anisyldiphenylsulfonium hexafluoroantimonate, 4-butoxyphenyldiphenylsulfonium tetrafluoroborate, 4-chlorophenyldiphenylsulfonium hexafluorophosphate, tri(4-phenoxyphenyl)sulfonium hexafluorophosphate, di(4-ethoxyphenyl)methylsulfonium hexafluoroarsenate, 4-acetonylphenyldiphenylsulfonium tetrafluoroborate, 4-thiomethoxyphenyldiphenylsulfonium hexafluorophosphate, di(methoxysulfonylphenyl)methylsulfonium hexafluoroantimonate, di(nitrophenyl)phenylsulfonium hexafluoroantimonate, di(carbomethoxyphenyl)methylsulfonium hexafluorophosphate, 4-acetamidophenyldiphenylsulfonium tetrafluoroborate, dimethylnaphthylsulfonium hexafluorophosphate, trifluoromethyldiphenylsulfonium tetrafluoroborate, p-(phenylthiophenyl)diphenylsulfonium hexafluoroantimonate, p-(phenylthiophenyl)diphenylsulfonium hexafluorophosphate, di-[p-(phenylthiophenyl)]phenylsulfonium hexafluoroantimonate, di-[p-(phenylthiophenyl)]phenylsulfonium hexafluorophosphate, 4,4′-bis(diphenylsulfonium)diphenylsulfide bis(hexafluoroantimonate), 4,4′-bis(diphenylsulfonium)diphenylsulfide bis(hexafluorophosphate), 10-methylphenoxathiinium hexafluorophosphate, 5-methylthianthrenium hexafluorophosphate, 10-phenyl-9,9-dimethylthioxanthenium hexafluorophosphate, 10-phenyl-9-oxothioxanthenium tetrafluoroborate, 5-methyl-10-oxothianthrenium tetrafluoroborate, 5-methyl-10,10-dioxothianthrenium hexafluorophosphate and mixtures thereof.

Typical sulfonium salts include triaryl-substituted salts such as mixed triarylsulfonium hexafluoroantimonate (for example, UVI-6974 available from Dow Chemical Company), mixed triarylsulfonium hexafluorophosphate (for example, UVI-6990 available from Dow Chemical Company), and arylsulfonium hexafluorophosphate salt (for example, SARCAT KI85 available from Sartomer Company).

The provided multi-photon photoinitiator systems can also include an electron donor compound. Electron donor compounds useful in the one-photon photoinitiator system of the photoreactive compositions are those compounds (other than the one-photon photosensitizer itself) that are capable of donating an electron to an electronic excited state of the one-photon photosensitizer. Such compounds may be used, optionally, to increase the one-photon photosensitivity of the photoinitiator system, thereby reducing the exposure required to effect photoreaction of the photoreactive composition. The electron donor compounds preferably have an oxidation potential that is greater than zero and less than or equal to that of p-dimethoxybenzene. Preferably, the oxidation potential is between about 0.3 and 1 volt vs. a standard saturated calomel electrode (“S.C.E.”).

The electron donor compound is also typically soluble in the reactive species and is selected based in part upon shelf stability considerations (as described above). Suitable donors are generally capable of increasing the speed of cure or the image density of a photoreactive composition upon exposure to light of the desired wavelength.

In general, electron donor compounds suitable for use with particular one-photon photosensitizers and photoinitiators can be selected by comparing the oxidation and reduction potentials of the three components (as described, for example, in U.S. Pat. No. 4,859,572 (Farid et al.)). Such potentials can be measured experimentally (for example, by the methods described by R. J. Cox, Photographic Sensitivity, Chapter 15, Academic Press (1973)) or can be obtained from references such as N. L. Weinburg, Ed., Technique of Electroorganic Synthesis Part II Techniques of Chemistry, Vol. V (1975), and C. K. Mann and K. K. Barnes, Electrochemical Reactions in Nonaqueous Systems (1970). The potentials reflect relative energy relationships and can be used in the following manner to guide electron donor compound selection:

If the reduction potential of the photoinitiator is less negative (or more positive) than that of the one-photon photosensitizer, an electron in the higher energy orbital of the one-photon photosensitizer is readily transferred from the one-photon photosensitizer to the lowest unoccupied molecular orbital (LUMO) of the photoinitiator, since this represents an exothermic process. Even if the process is instead slightly endothermic (that is, even if the reduction potential of the one-photon photosensitizer is up to 0.1 volt more negative than that of the photoinitiator) ambient thermal activation can readily overcome such a small barrier.

In an analogous manner, if the oxidation potential of the electron donor compound is less positive (or more negative) than that of the one-photon photosensitizer, an electron moving from the HOMO of the electron donor compound to the orbital vacancy in the one-photon photosensitizer is moving from a higher to a lower potential, which again represents an exothermic process. Even if the process is slightly endothermic (that is, even if the oxidation potential of the one-photon photosensitizer is up to 0.1 volt more positive than that of the electron donor compound), ambient thermal activation can readily overcome such a small barrier.

Slightly endothermic reactions in which the reduction potential of the one-photon photosensitizer is up to 0.1 volt more negative than that of the photoinitiator, or the oxidation potential of the one-photon photosensitizer is up to 0.1 volt more positive than that of the electron donor compound, occur in every instance, regardless of whether the photoinitiator or the electron donor compound first reacts with the one-photon photosensitizer in its excited state. When the photoinitiator or the electron donor compound is reacting with the one-photon photosensitizer in its excited state, it is preferred that the reaction be exothermic or only slightly endothermic. When the photoinitiator or the electron donor compound is reacting with the one-photon photosensitizer ion radical, exothermic reactions are still preferred, but still more endothermic reactions can be expected in many instances to occur. Thus, the reduction potential of the one-photon photosensitizer can be up to 0.2 volt (or more) more negative than that of a second-to-react photoinitiator, or the oxidation potential of the one-photon photosensitizer can be up to 0.2 volt (or more) more positive than that of a second-to-react electron donor compound.

Suitable electron donor compounds include, for example, those described by D. F. Eaton in Advances in Photochemistry, edited by B. Voman et al., Volume 13, pp. 427-488, John Wiley and Sons, New York (1986); in U.S. Pat. No. 6,025,406 (Oxman et al.); and in U.S. Pat. No. 5,545,676 (Palazzotto et al.). Such electron donor compounds include amines (including triethanolamine, hydrazine, 1,4-diazabicyclo[2.2.2]octane, triphenylamine (and its triphenylphosphine and triphenylarsine analogs), aminoaldehydes, and aminosilanes), amides (including phosphoramides), ethers (including thioethers), ureas (including thioureas), sulfinic acids and their salts, salts of ferrocyanide, ascorbic acid and its salts, dithiocarbamic acid and its salts, salts of xanthates, salts of ethylene diamine tetraacetic acid, alkyl borate salts, (alkyl)ₚ(aryl)_{q}borates (p+q=4) (for example, tetraalkylammonium salts), various organometallic compounds such as SnR₁₃ compounds (where each R₁₃ is independently chosen from among alkyl, aralkyl (for example, benzyl), aryl, and alkaryl groups) (for example, such compounds as n-C₃H₇Sn(CH₃)₃, (allyl)Sn(CH₃)₃, and (benzyl)Sn(n-C₃H₇)₃), ferrocene, and the like, and mixtures thereof. The electron donor compound can be unsubstituted or can be substituted with one or more non-interfering substituents. Typical electron donor compounds contain an electron donor atom (such as a nitrogen, oxygen, phosphorus, or sulfur atom) and an abstractable hydrogen atom bonded to a carbon or silicon atom alpha to the electron donor atom.

Typical amine electron donor compounds include alkyl-, aryl-, alkaryl- and aralkyl-amines (for example, methylamine, ethylamine, propylamine, butylamine, triethanolamine, amylamine, hexylamine, 2,4-dimethylaniline, 2,3-dimethylaniline, o-, m- and p-toluidine, benzylamine, aminopyridine, N,N′-dimethylethylenediamine, N,N′-diethylethylenediamine, N,N′-dibenzylethylenediamine, N,N′-diethyl-1,3-propanediamine, N,N′-diethyl-2-butene-1,4-diamine, N,N′-dimethyl-1,6-hexanediamine, piperazine, 4,4′-trimethylenedipiperidine, 4,4′-ethylenedipiperidine, p-N,N-dimethyl-aminophenethanol and p-N-dimethylaminobenzonitrile); aminoaldehydes (for example, p-N,N-dimethylaminobenzaldehyde, p-N,N-diethylaminobenzaldehyde, 9-julolidine carboxaldehyde, and 4-morpholinobenzaldehyde); and aminosilanes (for example, trimethylsilylmorpholine, trimethylsilylpiperidine, bis(dimethylamino)diphenylsilane, tris(dimethylamino)methylsilane, N,N-diethylaminotrimethylsilane, tris(dimethylamino)phenylsilane, tris(methylsilyl)amine, tris(dimethylsilyl)amine, bis(dimethylsilyl)amine, N,N-bis(dimethylsilyl)aniline, N-phenyl-N-dimethylsilylaniline, and N,N-dimethyl-N-dimethylsilylamine); and mixtures thereof. Tertiary aromatic alkylamines, particularly those having at least one electron-withdrawing group on the aromatic ring, have been found to provide especially good shelf stability. Good shelf stability has also been obtained using amines that are solids at room temperature. Good photographic speed has been obtained using amines that contain one or more julolidinyl moieties.

Typical amide electron donor compounds include N,N-dimethylacetamide, N,N-diethylacetamide, N-methyl-N-phenylacetamide, hexamethylphosphoramide, hexaethylphosphoramide, hexapropylphosphoramide, trimorpholinophosphine oxide, tripiperidinophosphine oxide, and mixtures thereof.

Typical alkylarylborate salts include:

Ar₃B(n-C₄H₉)⁻N(C₂H₅)₄⁺, Ar₃B(n-C₄H₉)⁻N(CH₃)₄⁺, Ar₃B(n-C₄H₉)⁻N(n-C₄H₉)₄⁺, Ar₃B(n-C₄H₉)⁻Li⁺, Ar₃B(n-C₄H₉)⁻N(C₆H₁₃)₄⁺, Ar₃B(C₄H₉)⁻N(CH₃)₃(CH₂)₂CO₂(CH₂)₂CH₃⁺, Ar₃B(C₄H₉)⁻N(CH₃)₃(CH₂)₂OCO(CH₂)₂CH₃⁺, Ar₃B(sec-C₄H₉) CH₃)₃(CH₂)₂CO₂(CH₂)₂CH₃⁺, AB(sec-C₄H₉)⁻N(C₆H₁₃)₄⁺, Ar₃B(C₄H₉)⁻N(C₈H₁₇)₄⁺, Ar₃B(C₄H₉)⁻N(CH₃)₄⁺, p-CH₃O—C₆H₄)₃B(n-C₄H₉)⁻N(n-C₄H₉)₄⁺, Ar₃B(C₄H₉)⁻N(CH₃)₃(CH₂)₂OH⁺, ArB(n-C₄H₉)₃⁻N(CH₃)₄⁺, ArB(C₂H₅)₃⁻N(CH₃)₄⁺, Ar₂B(n-C₄H₉)₂⁻N(CH₃)₄⁺, Ar₃B(C₄H₉)⁻N(C₄H₉)₄⁺, Ar₄B⁻N(C₄B₉)₄⁺, ArB (CH₃)₃⁻N(CH₃)₄⁺, (n-C₄H₉)₄B⁻N(CH₃)₄⁺, and Ar₃B(C₄H₉)⁻P(C₄H₉)₄⁺ (where Ar is phenyl, naphthyl, substituted (preferably, fluoro-substituted) phenyl, substituted naphthyl, and like groups having greater numbers of fused aromatic rings), as well as tetramethylammonium n-butyltriphenylborate and tetrabutylammonium n-hexyl-tris(3-fluorophenyl)borate (available as CGI 437 and CGI 746 from Ciba Specialty Chemicals Corporation, Tarrytown, N.Y.), and mixtures thereof.

The provided prepolymer can also include an adhesion promoter. The adhesion promoter can be used to enhance the adhesion of the acrylic prepolymer to surfaces, such as glass surfaces, after polymerization. Typically, alkoxylated multifunctional monomers such as alkoxylated trifunctional acrylic esters such as SR 9008 (available from Sartomer, Exton, Pa.) can be employed as adhesion promoters in the provided acrylic photopolymer system.

The provided method includes imagewise exposing at least one or more voxels of the photocurable composition described above to a dose of electromagnetic energy under conditions that are effective to photodefineably form at least one solid (or crosslinked) voxel of a three-dimensional microstructure having a volume. The volume of the solid voxel varies inversely with the dose of electromagnetic energy. That is, after a threshold dose of electromagnetic radiation higher doses of electromagnetic radiation the solid voxel size decreases as the dose of electromagnetic energy is increased.

The photocurable composition includes a photoinitiator system capable of simultaneous absorption of at least two photons and imagewise exposing (voxel by voxel) the multi-photon-absorbing composition with light sufficient to cause the photoinitiator system to absorb at least two photons, wherein the exposure takes place in a three-dimensional pattern by stepwise exposure. One or more portions of the composition are imagewise exposed to the electromagnetic energy under conditions effective to photodefinably form at least a portion of a three-dimensional microstructure or nanostructure. Photocurable compositions that are effective to photodefineably form at least a portion of a three-dimensional microstructure and photodefinability are further described in U.S. Pat. No. 6,855,478 (DeVoe et al.).

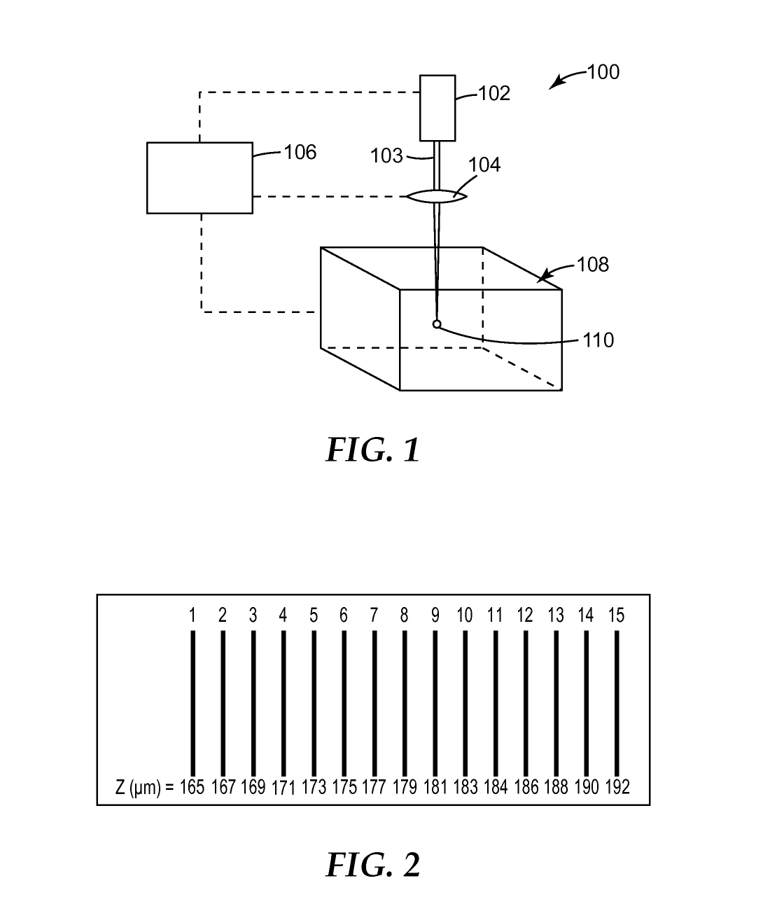

FIG. 1 schematically illustrates one methodology for producing three-dimensional microstructures and nanostructures. Referring to FIG. 1, system 100 includes laser light source 102 that directs laser beam 103 through optical lens system 104. Optical lens system 104 is further illustrated in FIG. 2. Lens system 104 focuses laser light 103 within focal region (voxel) 110 within body 108 that includes a composition that comprises a polymerizable mixture. A suitable translation mechanism, represented by 106 provides relative movement between body 108, optical lens system 104 and/or focal region 110 in three dimensions to allow the focal region to be positioned at any desired location within body 108. This relative movement can occur by physical movement of light source 102, optical lens system 104, and/or body 108, and may form one or more three-dimensional structures within body 108. One suitable translation system can include a mirror-mounted galvanometer with a moving (translation) stage.

Because the provided photocurable composition has contrast curves with a region where the slope is greater than zero and a region where the slope is less than zero, sub-diffraction limited resolution can be achieved by combining an imaging beam from the region of the contrast curve where the slope is greater than or equal to zero with a shaped deactivation beam from the region of the contrast curve where the slope is less than zero. The shape of the deactivation beam can be, for example, a Gauss-Laguerre mode, commonly described as a “doughnut” or a torus shape, or a Gauss-Hermite mode, which can be formed with an appropriate phase mask. The imaging and the deactivation beams are combined using, for example, a polarizing beam splitter and focused into the photoresist. The rest of the process, for example, translation of beam and photoresist relative to each other and image development, is as described elsewhere.

Typically, the same light source is used for both beams, simplifying the enhanced-resolution exposure apparatus. Because the timing delay of the imaging and deactivation pulses is constrained to be less than about a millisecond, preferably less than 100 microseconds, it is possible to use the same light source for both beams, especially is the repetition rate of the pulses is greater than about one kilohertz. The beam from the single light source may be split into two beams of equal or unequal power (ratio of powers 1:100 to 100:1), by means such as a polarizing beam splitter. The two beams are subsequently recombined and used in the manner described above.

Useful exposure systems include at least one light source (usually a pulsed laser) and at least one optical element. Typically, light sources include, for example, femtosecond near-infrared titanium sapphire oscillators (for example, a Coherent Mira Optima 900-F) pumped by an argon ion laser (for example, a Coherent Innova). This laser, operating at 76 MHz, has a pulse width of less than 200 femtoseconds, is tunable between 700 and 980 nm, and has average power up to 1.4 Watts.

Another example is a Spectra Physics “MAI TAI” Ti:sapphire laser system, operating at 80 MHz, average power about 0.85 Watts, tunable from 750 to 850 nm, with a pulse width of about 100 femtoseconds. However, in practice, any light source that provides sufficient intensity (to effect multi-photon absorption) at a wavelength appropriate for the photosensitizer (used in the photoreactive composition) can be utilized. Such wavelengths can generally be in the range of about 300 to about 1500 nm; preferably, from about 600 to about 1100 nm; more preferably, from about 750 to about 850 nm.

Q-switched Nd:YAG lasers (for example, a Spectra-Physics Quanta-Ray PRO), visible wavelength dye lasers (for example, a Spectra-Physics Sirah pumped by a Spectra-Physics Quanta-Ray PRO), and Q-switched diode pumped lasers (for example, a Spectra-Physics FCbar™) also can be utilized.

One skilled in the art can choose appropriate settings for using such laser systems to carry out multi-photon polymerization. For example, pulse energy per square unit of area (Eₚ) can vary within a wide range and factors such as pulse duration, intensity, and focus can be adjusted to achieve the desired curing result in accordance with conventional practices and knowledge of the contrast curve for the specific photoresist determined experimentally. If Eₚ is too high, the material being cured can be ablated or otherwise degraded. If Eₚ is too low, curing may not occur or may occur too slowly.

In terms of pulse duration when using near infrared pulsed lasers, preferred a preferred pulse length is generally less than about 10⁻⁸ second, more preferably less than about 10⁻⁹ second, and most preferably less than about 10⁻¹¹ second. Laser pulses in the femtosecond regime are most preferred as these provide a relatively large window for setting Eₚ levels that are suitable for carrying out multi-photon curing. With picosecond pulses, the operational window is not as large. With nanosecond pulses, curing may proceed slower than might be desired in some instances or not at all. With such relatively long pulses, the Eₚ level may need to be established at a low level to avoid material damage when the pulses are so long, relatively.

The provided method can further include removing material that has not been exposed to the light. The multi-photon-absorbing composition can include a curable species. That is, the photodefinable species can be a curable material. Alternatively, it can be a material that is depolymerized, for example, by absorption of the photons. Typically, the material is a curable material and removing material that has not been exposed to the light includes removing the uncured material. This removal step (developing) can occur using a variety of techniques, one of which involves dissolving uncured material in a suitable solvent. The provided method includes developing at least partially, the photodefinably formed portion of the three-dimensional microstructure.

Objects and advantages of this invention are further illustrated by the following examples, but the particular materials and amounts thereof recited in these examples, as well as other conditions and details, should not be construed to unduly limit this invention.

### EXAMPLES

### Comparative Example 1

### Two-Photon Writing Speed Threshold and Voxel Dimension Measurement for IRGACURE 369 in PMMA

A simple two-photon writing system was used to investigate writing speed threshold and voxel height. It was designed to cover features over a small area (0.1 mm²) and was equipped with an IMRA ultrafast fiber laser having a center wavelength of 807 nm and a pulse width of 112 fs, laser beam power control, air objective (40×, numerical aperture 0.95), and electromagnetic shutter synchronized with the CAD file according to the writing parameters. Samples were mounted on a Newport piezoelectric micro/nanopositioning X,Y,Z stage that was driven via computer. An Ocean Optics confocal interface detection system was used to accurately and precisely determine the location of the substrate-photoresist interface. This system had scan rates of about 1-300 micrometers (μm) per second.

To accurately find the substrate interface, a series of 15 lines were written at a 25 μm spacing, varying the at 2 μm intervals along the z axis, centered around zₒ (FIG. 2) where a peak of the reflected laser beam from the interface was detected by a fiber spectrum detector. For each sample film, this sequence of 15 lines was repeated at speeds ranging from 1 to 200 μmils. The samples are then dipped in Shipley SU8 developer for 5 minutes followed by a rinse with isopropanol, and finally air dried. The development process removes the uncured resin from the sample, leaving some number of cured lines attached to the sample substrate.

Since exposed lines written too high or too low in the z axis would be written above, or below the substrate interface, and hence not be properly anchored to the substrate, we were able to determine the interface location and a measurement of voxel height from the number of lines that survive development. Using the number of cured lines (s) and the z interval (2 μm) resulted in a measure of voxel size ((s−1)*2) for a given material, laser power, photosensitive dye concentration, and write speed. If the power and speed used are above the threshold dose for the sample used, cured lines will be present. As the power was reduced, or the write speed was increased, fewer lines survived development. The point at which lines no longer remain was determined to be the threshold dosage.

Employing the method described above, the voxel size for a film containing 0.5 wt % 2-benzyl-2-dimethylamino-1-(4-morpholinophenyl)-butanone-1 (IRGACURE 369, available from BASF) in poly(methyl methacrylate) stock film vs. 1/writing speed was measured for four laser power levels. The PMMA stock contained a mixture of three kinds of acrylate monomers (16.5 wt % PMMA (120 k MW)+19.25 wt % alkoxylated multifunctional acrylate monomer (SR368, available from Sartomer, Exton, Pa.)+19.25 wt % triacrylate monomer (SR9008, also available from Sartomer) dissolved in cyclopentanone

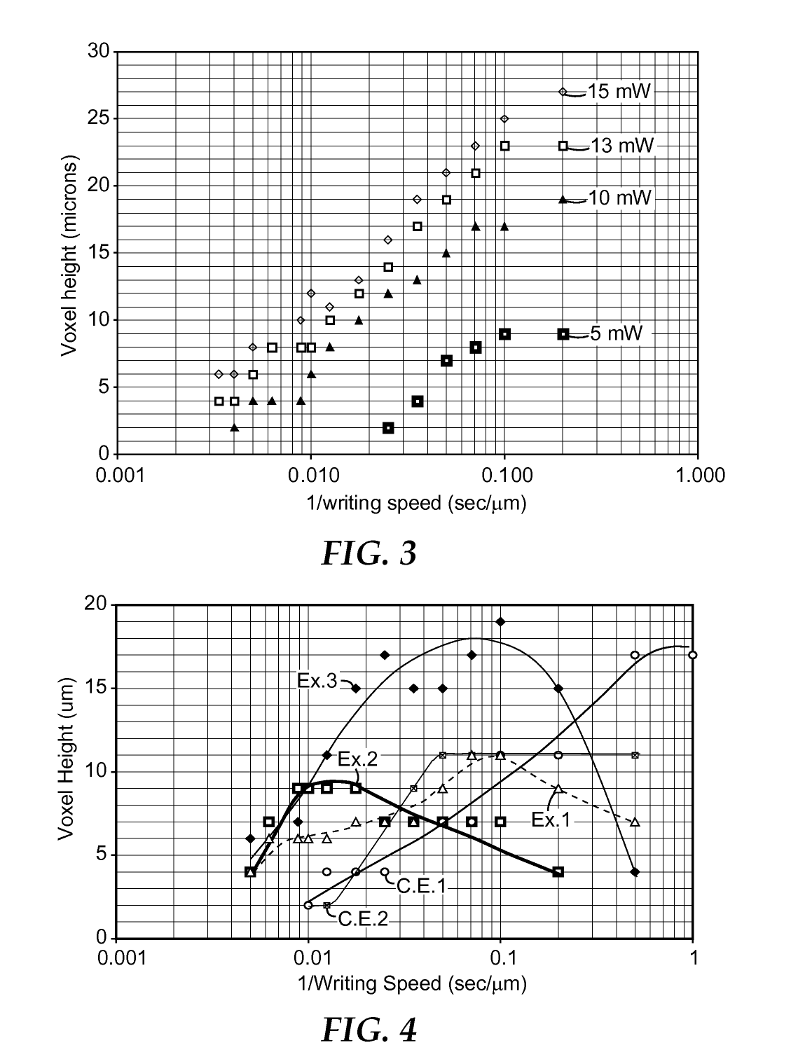

The results are plotted in FIG. 3 show very conventional behavior of voxel size for the commercially available IRGACURE 369 in PMMA film, in that as the dose (inverse write speed) increases, the voxel size increases proportionally for a range of laser power.

### Examples 1-4

### Two-Photon Writing Speed Threshold

TABLE 1
Compositions of Photocurable Resin Systems
(wt % in PMMA stock solution or SU-8 Photoresist
(Comparative Example 2)

| | | | 2P- | | | | |
|---|---|---|---|---|---|---|---|
| | Resin | I- | Photointiator | DPI - | DPI - | CGI | |
| Example | System | 369 | (Structure (IV)) | PF₆ | SbF₆ | 7460 | MCG |
| 1 | PMMA | | 0.05 | | | | |
| 2 | PMMA | | 0.05 | 0.50 | | | |
| 3 | PMMA | | 0.05 | 0.50 | | 1.0 | |
| C. E. 1 | PMMA | 0.5 | | | | | |
| C. E. 2 | SU-8 | | 0.05 | | 2.0 | | |
| C. E. 3 | PMMA | | | | | | 1.0 |

C. E.—Comparative Example
PMMA - PMMA stock solution described above.
SU-8 photoresist is an epoxy-based negative photoresist available from Micro Chem Corporation, Boston, MA.
2-P-photoinitiator having Structure (IV) was made using the same procedures described in Example 56 of U.S. Pat. No. 6,297,913 (Marder et al.) but using slightly different starting materials.
DPI-PF₆ and DPI-SbF₆ are diphenyliodonium hexafluorophosphate and hexafluoroantimonate, respectively.
CGI-7460 is tetrabutylammonium n-hexyl-tris(3-fluorphenyl)borate, available from CIBA Specialty Chemicals, now a part of BASF, Tarrytown, N.Y.
MCG—malachite green carbinol base hydrochloride.

Films were prepared as described in Comparative Example 1 above. They were subjected to the same procedures for writing 2-D 15-line sets for each kind of film at laser power levels that could show the threshold condition for each individual film as described above.

The results are displayed in FIG. 4. The voxel size showed a maximum as a function of inverse scan speed for Examples 1-3. These samples all contain an acrylic resin composition (PMMA stock solution) and a distyrylbenzene dye (the dye of Structure IV). In contrast, Comparative Example 1 (with no distyrylbenzene dye) and Comparative Example 2 (having an epoxy negative photoresist) did not show this effect.

### Examples 1-4

### Two-Photon Writing Speed Threshold

Four films were prepared and cubes 50 μm×50 μm×10 μm in dimension were written using Waverunner laser/scanner control software (by Nutfield Technology) to write slices spaced 0.5 μm apart, with each slice filled in by hatched lines also written 0.5 μm apart. Appropriate laser power levels and varying speeds were used.

### Example 2 and Comparative Examples 1-2

### Voxel Dimension Measurements

Four films were prepared from Example 2 and Comparative Examples 1-w and cubes 50 μm×50 μm×10 μm in dimension were written using Waverunner laser/scanner control software (by Nutfield Technology, Hudson, N.H.) to write slices spaced 0.5 μm apart, with each slice filled in by hatched lines also written 0.5 μm apart. Appropriate laser power levels and varying speeds were used. The surface roughness of the samples, after development, was measured by a nondestructive optical interference method, and is shown in Table 2.

TABLE 2
Surface Roughness vs. Scan Speed of Film Samples

| | Surface Roughness | | |
|---|---|---|---|
| Film Sample Composition | Scan Speed | | |
| Example 2, 6 mW, | 75 nm | 22 nm | 32 nm |
| (threshold >200 μm/s) | 28.3 μm/s | 40 μm/s | 160 μm/s |
| Comparative Example 1, 7 mW, | 19 nm | 40 nm | 42 nm |
| (threshold = 100 μm/s) | 10 μm/s | 28.3 μm/s | 56.6 μm/s |
| Comparative Example 2 2.5 mW | 7 nm | 4 nm | 12 nm |
| (threshold = 100 μm/s) | 10 μm/s | 40 μm/s | 160 μm/s |

Example 2 has higher surface roughness at slower speeds indicative of the voxel size shrinking as the write speed is lowered (dose increased). In contrast, Comparative Examples 1 and 2 do not show this higher roughness at slower write speeds.

TABLE 3
Photosensitizers Used in Examples 4-6

| | Photosensitizer |
|---|---|
| Example | (Structure Number) |
| 4 | (II) |
| 5 | (III) |
| 6 | (V) |

### Examples 4-6

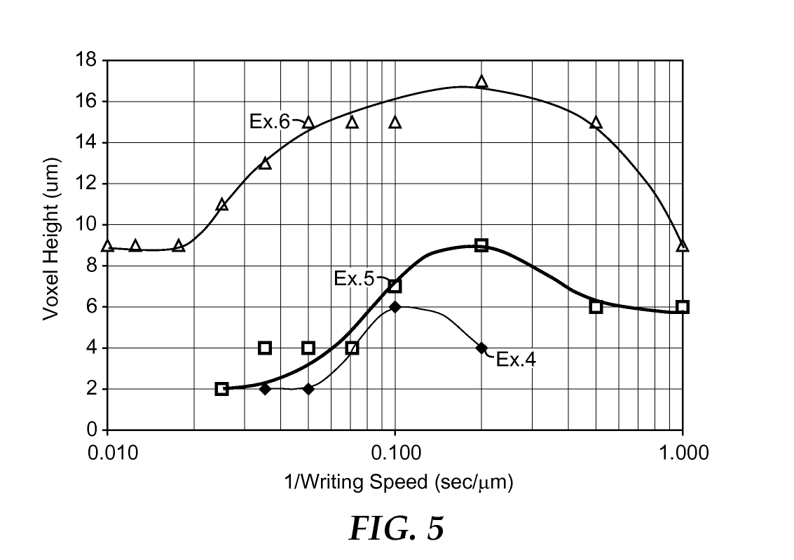

Films were prepared as in Example 1, with the photosensitizers listed in Table 3, below, substituted for the 2P-Photoinitiator (Structure (IV)). Voxel height as a function of reciprocal scanning speed (proportional to dose) was determined as in Example 1, and plotted in the figure below. The data show that for the dyes in Examples 4-6 is displayed in FIG. 5. There is a maximum in the voxel size vs. reciprocal scanning speed (dose) plot, voxel size decreasing with decreasing scan speed (increasing dose) in at least one part of the curve. Lines in the graph are shown to clarify trends.

Following are exemplary embodiments of an enhanced multi-photon imaging resolution method according to aspects of the present invention.

Embodiment 1 is a method of forming a three-dimensional microstructure comprising: providing a photocurable composition comprising: a prepolymer comprising an acrylate monomer, and a multi-photon photoinitiator system comprising at least one distyrylbenzene dye; and imagewise exposing at least one voxel of the photocurable composition to a dose of electromagnetic energy under conditions effective to photodefinably form at least one solid voxel of a three-dimensional microstructure having a volume, wherein the solid voxel volume is varies inversely with to the dose.

Embodiment 2 is a method of forming a three-dimensional microstructure according to embodiment 1, wherein the distyrylbenzene dye has the formula:

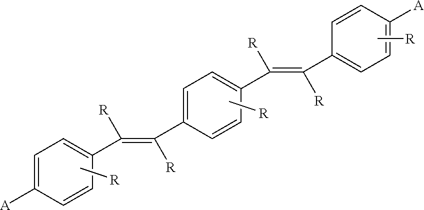

wherein each R is, independently, H, chloro, bromo, fluoro, cyano, methyl, ethyl, propyl, butyl, methoxy, ethoxy, propoxy, butoxy, or cyano, wherein each A is, independently, H, Cl, Br, NR₃R₄, OR₅, alkyl, alkenyl, aryl, and O(C═O)R₆, wherein R₃ to R₆ are, independently, methyl, ethyl, propyl, butyl, hydroxymethyl, hydroxyethyl, hydroxypropyl, hydroxybutyl, morphylino, phthalimido, and phenyl, and wherein the phenyl group, if present, is substituted on each ring position, independently, with H, methyl, ethyl, methoxy, ethyoxy, fluorine, trifluoromethane, or cyano.

Embodiment 3 is a method of forming a three-dimensional microstructure according to embodiment 2, wherein the distyrylbenzene dye is selected from

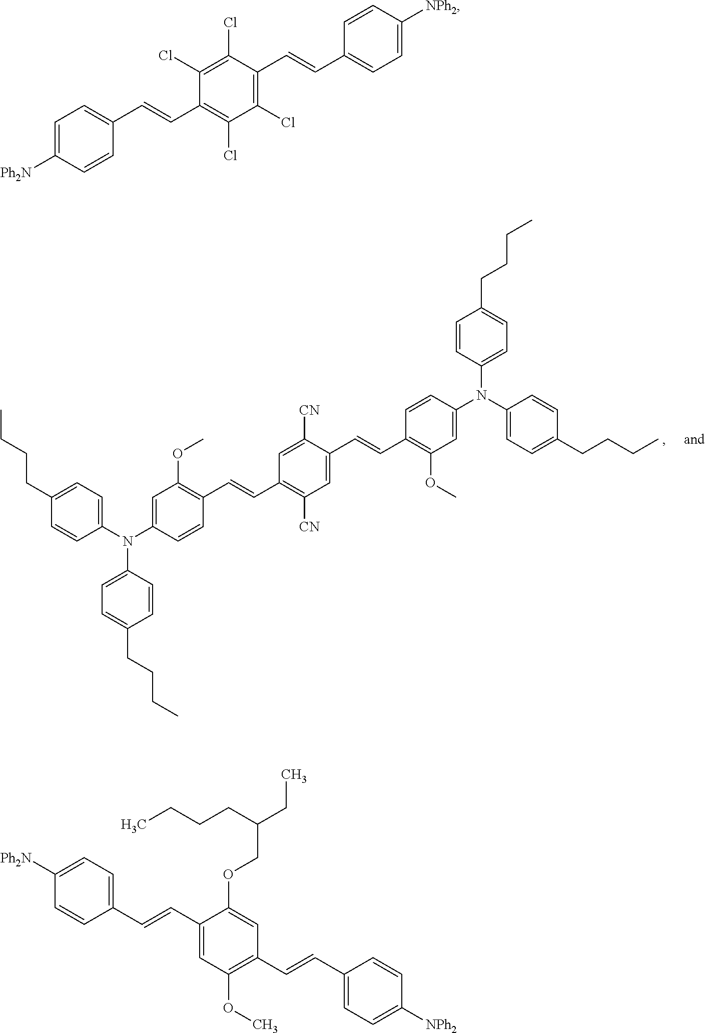

Embodiment 4 is a method of forming a three-dimensional microstructure according to embodiment 1, wherein the multi-photon photoinitiator system further comprises an onium salt.

Embodiment 5 is a method of forming a three-dimensional microstructure according to embodiment 4, wherein the onium salt comprises a diphenyliodonium salt.

Embodiment 6 is a method of forming a three-dimensional microstructure according to embodiment 1, wherein the multi-photon photoinitiator system further comprises an electron donor compound.

Embodiment 7 is a method of forming a three-dimensional microstructure according to embodiment 6, wherein the electron donor comprises an alkyl borate salt.

Embodiment 8 is a method of forming a three-dimensional microstructure according to embodiment 1, wherein at least a portion of at least one voxel receives a higher dose of electromagnetic energy than other portions of the voxel, and the portion receiving a higher dose of electromagnetic energy does not photodefinably form at least a portion of the three-dimensional microstructure.

Embodiment 9 is a method of forming a three-dimensional microstructure according to embodiment 1, further comprising developing at least partially, the photodefinably formed portion of the three-dimensional microstructure.

Embodiment 10 is a method of forming a three-dimensional microstructure according to Embodiment 1, wherein the prepolymer comprises an adhesion promoter.

Embodiment 11 is a method of forming a three-dimensional microstructure according to embodiment 10, wherein the adhesion promoter comprises an alkoxylated multifunctional acrylate monomer.

Embodiment 12 is a method of forming a three-dimensional microstructure comprising: providing a photocurable composition comprising: a prepolymer comprising an acrylate monomer, and a multi-photon photoinitiator system comprising at least one chromophore having the formula (T-Q)ₙ-N-Phₘ, wherein Q is a single bond or 1,4-phenylene, Ph is a phenyl group, n is 1-3, m has a value of (3-n) and (T-Q) has the formula:

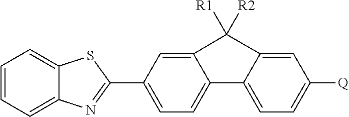

wherein R₁ and R₂ are alkyl groups having 1 to 20 carbon atoms provided that when Q is a single bond, the value of n is 2 or 3; and imagewise exposing at least one voxel of the photocurable composition to a dose of electromagnetic energy under conditions effective to photodefinably form at least one solid voxel of a three-dimensional microstructure having a volume, wherein the solid voxel volume is varies inversely with to the dose.

Embodiment 13 is a multi-photon resin system comprising: a photocurable composition comprising: a prepolymer comprising an acrylate monomer, and a multi-photon photoinitiator system comprising at least one distyrylbenzene dye or one chomophore having the formula

(T-Q)ₙ-N-Phₘ,

wherein Q is a single bond or 1,4-phenylene, Ph is a phenyl group, n is 1-3, m has a value of (3-n) and (T-Q) has the formula:

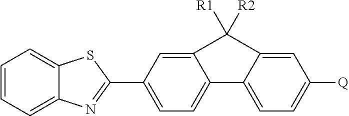

wherein R₁ and R₂ are alkyl groups having 1 to 20 carbon atoms provided that when Q is a single bond, the value of n is 2 or 3; wherein upon imagewise exposure of at least one voxel of the photocurable composition to a dose of electromagnetic energy under conditions effective to photodefinably form at least one solid voxel of a three-dimensional microstructure having a volume, and wherein the solid voxel volume is varies inversely with to the dose.

Embodiment 14 is a multi-photon resin system according to embodiment 13, wherein the multi-photon photoinitiator system further comprises an onium salt.

Embodiment 15 is a multi-photon resin system according to embodiment 13, wherein the onium salt comprises a diphenyliodonium salt.

Embodiment 16 is a multi-photon resin system according to embodiment 13, wherein the multi-photon photoinitiator system further comprises an electron donor compound.

Embodiment 17 is a multi-photon resin system according to embodiment 16, wherein the electron donor comprises an alkyl borate salt.

Embodiment 18 is a multi-photon resin system according to embodiment 13, wherein the distyrylbenzene dye is selected from

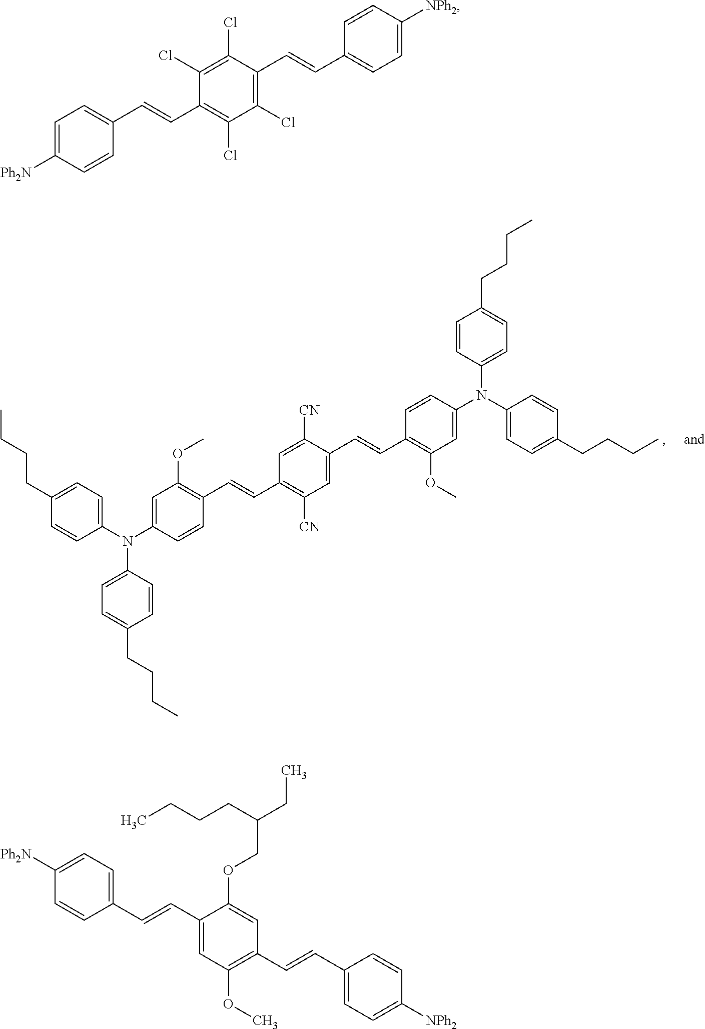

Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows. All references cited in this disclosure are herein incorporated by reference in their entirety.

1-17. (canceled)

18. A method of forming a three-dimensional microstructure comprising:
providing a photocurable composition comprising:
a prepolymer comprising an acrylate monomer, and
a multi-photon photoinitiator system comprising at least one distyrylbenzene dye; and
imagewise exposing at least one voxel of the photocurable composition to a dose of electromagnetic energy under conditions effective to photodefinably form at least one solid voxel of a three-dimensional microstructure having a volume, wherein the solid voxel volume varies inversely with the dose.

19. A method of forming a three-dimensional microstructure according to claim 18, wherein the distyrylbenzene dye has the formula: 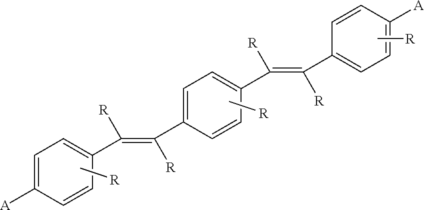
wherein each R is, independently, H, chloro, bromo, fluoro, cyano, methyl, ethyl, propyl, butyl, methoxy, ethoxy, propoxy, butoxy, or cyano;
wherein each A is, independently, H, Cl, Br, NR₃R₄, OR₅, alkyl, alkenyl, aryl, and O(C═O)R₆, wherein R₃ to R₆ are, independently, methyl, ethyl, propyl, butyl, hydroxymethyl, hydroxyethyl, hydroxypropyl, hydroxybutyl, morphylino, phthalimido, and phenyl; and
wherein the phenyl group, if present, is substituted on each ring position, independently, with H, methyl, ethyl, methoxy, ethoxy, fluorine, trifluoromethyl, or cyano.

20. A method of forming a three-dimensional microstructure according to claim 19, wherein the distyrylbenzene dye is selected from

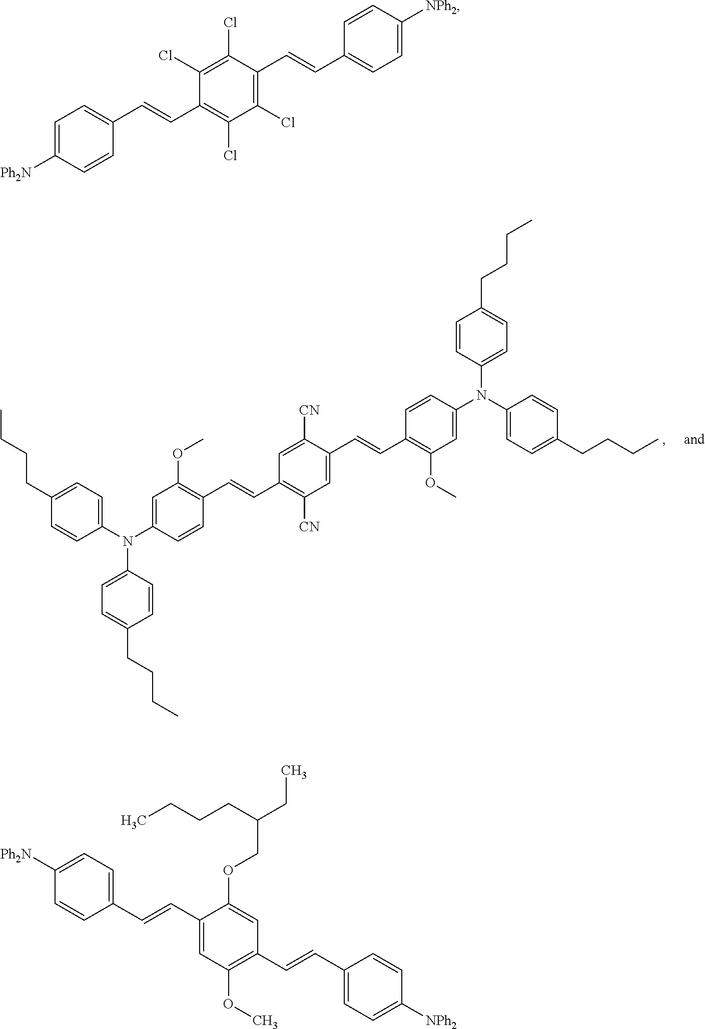

21. A method of forming a three-dimensional microstructure according to claim 18, wherein the multi-photon photoinitiator system further comprises an onium salt.

22. A method of forming a three-dimensional microstructure according to claim 21, wherein the onium salt comprises a diphenyliodonium salt.

23. A method of forming a three-dimensional microstructure according to claim 18, wherein the multi-photon photoinitiator system further comprises an electron donor compound.

24. A method of forming a three-dimensional microstructure according to claim 23, wherein the electron donor comprises an alkyl borate salt.

25. A method of forming a three-dimensional microstructure according to claim 18, wherein at least a portion of at least one voxel receives a higher dose of electromagnetic energy than other portions of the voxel, and the portion receiving a higher dose of electromagnetic energy does not photodefinably form at least a portion of the three-dimensional microstructure.

26. A method of forming a three-dimensional microstructure according to claim 18, further comprising developing at least partially, the photodefinably formed portion of the three-dimensional microstructure.

27. A method of forming a three-dimensional microstructure according to claim 18, wherein the prepolymer comprises an adhesion promoter.

28. A method of forming a three-dimensional microstructure according to claim 27, wherein the adhesion promoter comprises an alkoxylated multifunctional acrylate monomer.

29. A method of forming a three-dimensional microstructure comprising:
providing a photocurable composition comprising:
a prepolymer comprising an acrylate monomer, and
a multi-photon photoinitiator system comprising at least one chromophore having the formula (T-Q)ₙ-N-Phₘ,
wherein Q is a single bond or 1,4-phenylene, Ph is a phenyl group, n is 1-3, m has a value of (3-n) and (T-Q) has the formula: 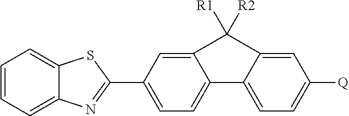
wherein R₁ and R₂ are alkyl groups having 1 to 20 carbon atoms provided that when Q is a single bond, the value of n is 2 or 3; and
imagewise exposing at least one voxel of the photocurable composition to a dose of electromagnetic energy under conditions effective to photodefinably form at least one solid voxel of a three-dimensional microstructure having a volume, wherein the solid voxel volume varies inversely with the dose.

30. A multi-photon resin system comprising:
a photocurable composition comprising:
a prepolymer comprising an acrylate monomer, and a multi-photon photoinitiator system comprising at least one distyrylbenzene dye or one chomophore having the formula
(T-Q)ₙ-N-Phₘ,
wherein Q is a single bond or 1,4-phenylene, Ph is a phenyl group, n is 1-3, m has a value of (3-n) and (T-Q) has the formula: 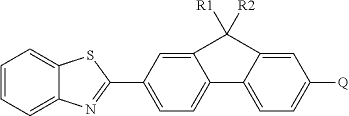
wherein R₁ and R₂ are alkyl groups having 1 to 20 carbon atoms provided that when Q is a single bond, the value of n is 2 or 3;
wherein upon imagewise exposure of at least one voxel of the photocurable composition to a dose of electromagnetic energy under conditions effective to photodefinably form at least one solid voxel of a three-dimensional microstructure having a volume, and wherein the solid voxel volume varies inversely with the dose.

31. A multi-photon resin system according to claim 30, wherein the multi-photon photoinitiator system further comprises an onium salt.

32. A multi-photon resin system according to claim 30, wherein the onium salt comprises a diphenyliodonium salt.

33. A multi-photon resin system according to claim 30, wherein the multi-photon photoinitiator system further comprises an electron donor compound.

34. A multi-photon resin system according to claim 33, wherein the electron donor comprises an alkyl borate salt.
